(19) United States
(12) Patent Application Publication
(10) Pub. No.: US 2018/0053662 A1
(43) Pub. Date: Feb. 22, 2018

(54) TEXTURING OF SILICON SURFACE WITH DIRECT-SELF ASSEMBLY PATTERNING

(71) Applicant: GLOBALFOUNDRIES Inc., Grand Cayman (KY)

(72) Inventors: Bartlomiej Jan PAWLAK, Leuven (BE); Harry J. LEVINSON, Saratoga, CA (US)

(21) Appl. No.: 15/238,760

(22) Filed: Aug. 17, 2016

(51) Int. Cl. H01L 21/308; H01L 21/306; H01L 29/04; H01L 21/02

(52) U.S. Cl. CPC H01L 21/3086; H01L 21/30604; H01L 29/045; H01L 21/02381; H01L 21/02502; H01L 21/0245; H01L 21/02461; H01L 21/02463; H01L 21/0243

(57) ABSTRACT

A method of texturing a silicon (Si) wafer and the resulting device are provided. Embodiments include forming a mask over an upper surface of a Si wafer; patterning the mask by direct-self assembly (DSA); etching the Si wafer through the patterned mask to form holes in the Si wafer; removing the mask; and etching the holes to form a textured surface in the Si wafer.

### TECHNICAL FIELD

The present disclosure relates to the manufacture of semiconductor devices. In particular, the present disclosure relates to texturing of silicon (Si) wafers used in manufacturing a semiconductor device in the 14 nm technology nodes and beyond.

### BACKGROUND

With Si wafers, epitaxial growth of different semiconductor materials having different lattice constants and thermal coefficients results in the generation of defects, such as dislocation defects, which in turn lead to poor transistor performance and reliability issues. Substrates with stress relaxed buffer (SRB) layers, including gallium arsenide (GaAs) or silicon germanium (SiGe) stepped or graded, are useful in achieving stress relaxation. However, very thick SiGe SRB wafers (e.g., ranging between 2 μm to 7 μm) can have defect densities surpassing industry targets of 1e3/cm² or less. Promising results have been achieved when epitaxial growth is performed on a conventional wafer with <111> textured surface consisting of uniformly distributed pyramids. However, when random texturing of the Si surface is performed, very large patterned structures (e.g., ranging between 1 μm and 2 μm) are formed, which leads to a thicker SRB which increases cost.

A need therefore exists for methodology enabling the formation of smaller, denser and uniformly distributed textured structures on Si surfaces, for application of a thinner SRB layer, and the resulting device.

### SUMMARY

An aspect of the present disclosure includes an economical patterning method for triggering the formation of small, dense and uniformly distributed structures on a Si surface. In certain aspects, the patterning method is direct-self assembly (DSA) patterning.

Another aspect of the present disclosure is a device including a Si wafer having a textured surface including a uniform distribution of small pyramids.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a mask over an upper surface of a Si wafer; patterning the mask by DSA; etching the Si wafer through the patterned mask to form holes in the Si wafer; removing the mask; and etching the holes to form a textured surface in the Si wafer.

Aspects of the present disclosure include wet or dry etching the Si wafer through the patterned mask to form the holes in a uniform distribution having a separation of 30 to 300 nm between adjacent holes and an individual hole diameter of 10 to 300 nm. Other aspects include direction-preferential etching the holes to form the textured surface in the Si wafer. Further aspects include direction-preferential etching with tetramethylammonium hydroxide (TMAH), hydrogen chloride (HCl) or potassium hydroxide (KOH). Additional aspects include etching the holes to form the textured surface by forming pyramids having a depth of 50 to 300 nm in the upper surface of the Si wafer. Further aspects include the pyramids having a Si <111> surface. Additional aspects include forming the textured surface by forming inverted pyramids having a Si <111> surface. Another aspect includes epitaxially growing a low-temperature seed layer on the textured surface of the Si wafer; forming a SRB layer over the low-temperature seed layer; and planarizing an upper surface of the SRB layer. Additional aspects include planarizing the upper surface of the SRB layer with chemical-mechanical planarization (CMP) and includes epitaxially growing the low-temperature seed layer in trenches of the textured surface of the Si wafer. Another aspect includes forming a graded SRB stacked epitaxial layer on the textured surface of the Si wafer. Further aspects include epitaxially growing the low-temperature seed layer to a thickness of 10 nm to 40 nm. Another aspect includes the low-temperature seed layer including germanium (Ge), indium phosphide (InP), or GaAs. Additional aspects include epitaxially growing the SRB layer over the low-temperature seed layer to a thickness of 200 nm to 500 nm, wherein the SRB layer includes silicon germanium (SiₓGe₁₋ₓ), indium gallium arsenide (InGaAs), or indium gallium arsenide phosphide (GaₓIn₁₋ₓAs_{y}P_{1-y}).

Another aspect of the present disclosure is a method including: forming a mask over an upper surface of a Si wafer; patterning the mask by DSA; etching the Si wafer through the patterned mask to form holes in the Si wafer; removing the mask; etching the holes to form a textured surface in the Si wafer, wherein the textured surface includes a Si <111> surface; epitaxially growing a low-temperature seed layer on the textured surface of the Si wafer, the low-temperature seed layer including Ge, InP, or GaAs; epitaxially growing a SRB layer over the low-temperature seed layer to a thickness of 200 nm to 300 nm, wherein the SRB layer includes SiₓGe₁₋ₓ, InGaAs, or GaₓIn₁₋ₓAs_{y}P_{1-y}; and planarizing an upper surface of the SRB layer.

Aspects include wet or dry etching the Si wafer through the patterned mask to form the holes in a uniform distribution having a separation of 30 to 300 nm between adjacent holes and an individual hole diameter of 10 to 300 nm. Further aspects include direction-preferential etching the holes to form the textured surface in the Si wafer to form pyramids in the upper surface of the Si wafer, wherein the pyramids have a depth of 50 to 300 nm. Additional aspects include direction-preferential etching with tetramethylammonium hydroxide (TMAH), hydrogen chloride (HCl) or potassium hydroxide (KOH).

Another aspect of the present disclosure is a device including a Si wafer having a textured surface including a uniform distribution of pyramids, the pyramids having a depth of less than 300 nm; an epitaxially grown low-temperature seed layer formed on the textured surface of the Si wafer; and a SRB layer deposited over the low-temperature seed layer.

Aspects include the uniform distribution of pyramids having a Si <111> surface. Other aspects include the low-temperature seed layer includes Ge, InP, or GaAs, and the SRB layer includes SiₓGe₁₋ₓ, InGaAs, or GaₓIn₁₋ₓAs_{y}P_{1-y}.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1, 2 and 3 schematically illustrate cross sectional views of a process flow to produce a textured Si wafer, in accordance with an exemplary embodiment;

FIG. 4 is a scanning electron microscope image of a DSA patterned Si wafer surface;

FIG. 5A schematically illustrates a cross sectional view of a process step in producing a SRB layer over a textured Si wafer, in accordance with an exemplary embodiment;

FIG. 5B is a drawing of pyramid shapes formed in surface of a DSA patterned Si wafer; and

FIGS. 6 and 7 schematically illustrate cross sectional views of a process flow to produce a SRB layer over a textured Si wafer, in accordance with an exemplary embodiment

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about”.

The present disclosure addresses and solves the current problem of defect density caused by thick SRB layers grown on textured Si wafers.

Methodology in accordance with embodiments of the present disclosure include forming a mask over an upper surface of a Si wafer; patterning the mask by DSA; etching the Si wafer through the patterned mask to form holes in the Si wafer; removing the mask; and etching the holes to form a textured surface in the Si wafer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

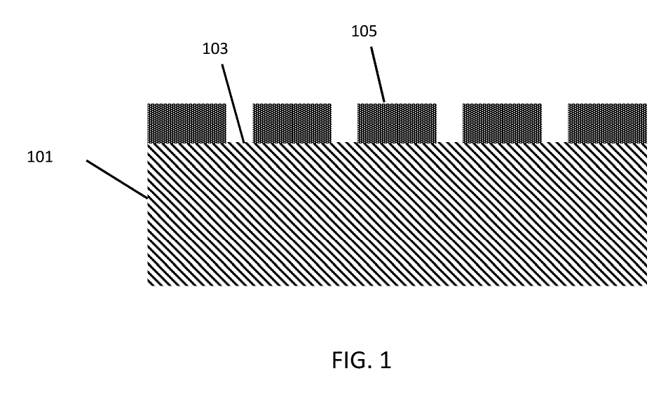

FIG. 1 illustrates, in cross section, an example of Si wafer 101 having a smooth upper surface 103. The Si wafer can have a variety of diameters from 25.4 mm to 450 mm and can be formed of a crystalline Si. The Si wafer serves as a substrate for microelectronic devices built in and over the wafer and undergoes many microfabrication process steps such as doping or ion implantation, etching, deposition of various materials, and photolithographic patterning. On top of the upper surface 103, a mask 105 is deposited and patterned. The patterning is performed by DSA. The mask 105 is formed of polymeric materials including polystyrene-poly-methylmethacrylate copolymers and formed to a thickness of 30-60 nm over the upper surface 103.

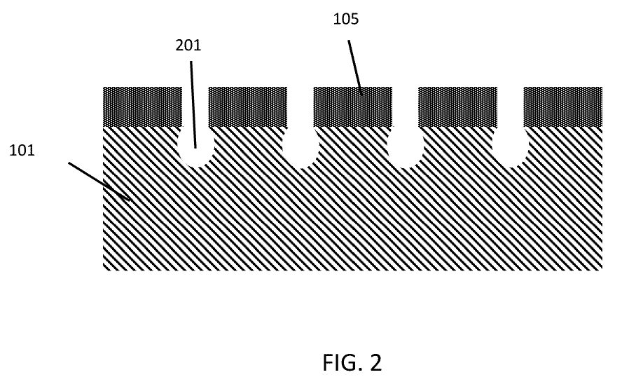

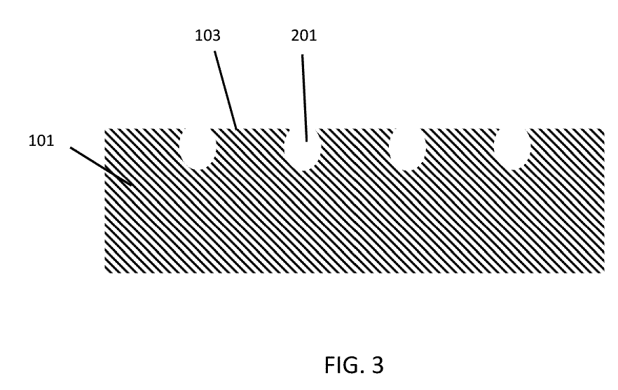

Adverting to FIG. 2, a wet or dry etching is performed to trigger a Si etch through the mask 105 and into the Si wafer 101. Holes 201 are formed in the Si wafer 101. In FIG. 3, the mask 105 is removed to reveal the surface 103 of the Si wafer 101 and holes 201. Dry etching can include a sulfur hexafluoride based dry etch. An aqueous solution of sodium hydroxide (NaOH) can be used as a wet etching solution.

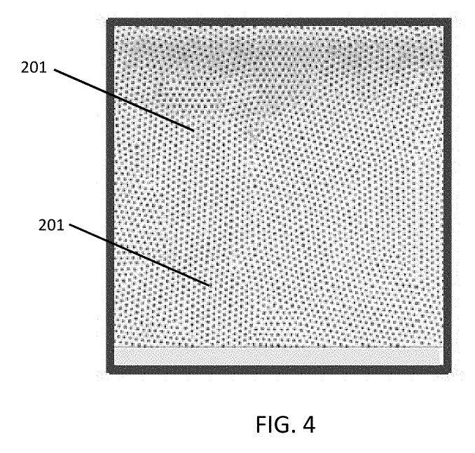

Adverting to FIG. 4, a scanning electron microscope image of the Si wafer 101 with the holes 201 is shown. The holes 201 have a uniform distribution, not a periodic distribution, with a separation of 30 to 300 nm between adjacent holes and an individual hole diameter of 10 to 300 nm.

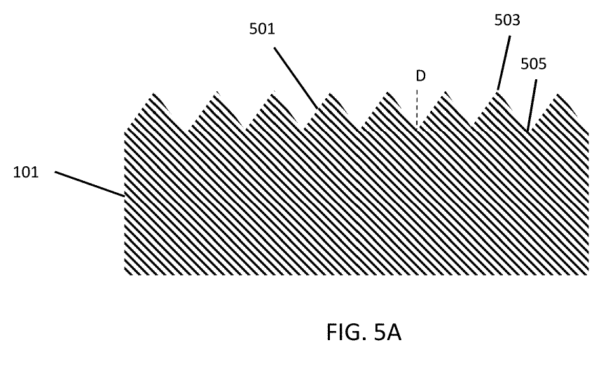

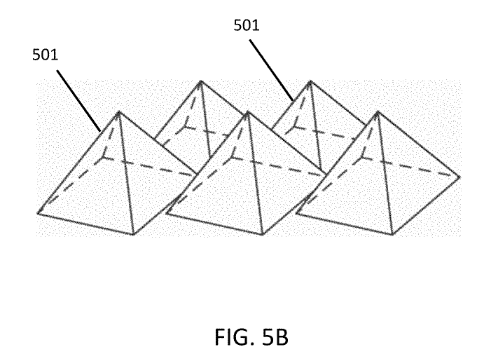

Adverting to FIG. 5A, the holes 201 of the Si wafer 101 are etched to form a textured surface in the Si wafer 101. The holes 201 are utilized to trigger etch spots to further form pyramid shapes 501. The plurality of pyramid shapes 501 are formed from holes 201 by a direction-preferential etch. The direction-preferential etching can be TMAH, HCl or KOH based. Since there is a short distance between adjacent holes, small, dense and uniformly distributed pyramids 501 can be formed on the entire surface of Si wafer 101. Each pyramid 501 has a depth D of 50 to 300 nm from peak 503 to trench 505. In certain examples, the pyramids have a depth of 50 to 100 nm. The pyramids 501 have a Si <111> surface. The pyramids 501 are uniformly distributed, not randomly distributed, across the entire surface of the Si wafer 101. Pyramids 501 have relatively sharp peaks 503 as opposed to peaks with truncated or flat surfaces. In FIG. 5B is a schematic drawing representing a portion of the uniformly distributed pyramids 501.

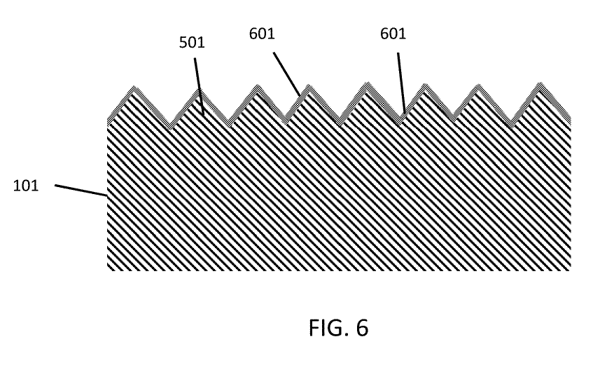

Adverting to FIG. 6, an epitaxially grown low-temperature seed layer 601 is formed on the textured surface of the Si wafer 101. In particular, the low-temperature seed layer 601 is formed over the pyramid shapes 501 such that the peaks 503 and trenches 505 are covered with the epitaxially grown low-temperature seed layer 601. The low-temperature seed layer 601 is grown to a thickness of 10 to 40 nm, for example 20 nm. The low-temperature seed layer 601 includes, for example, Ge, InP, or GaAs. The temperature at which the seed layer 601 is epitaxially grown ranges between 400 and 700° C. A chemical vapor deposition (CVD) or molecular beam epitaxy (MBE) processes can be used to epitaxially grow the seed layer 601. In certain examples the seed layer 601 may be skipped and substituted by graded SRB. For example, a graded SRB stacked epitaxial layer of Si/SiGe5%/SiGe10%/SiGe15%/SiGe20%+buffer SiGe 25%, which is thicker, can be formed on the textured surface of the Si wafer 101.

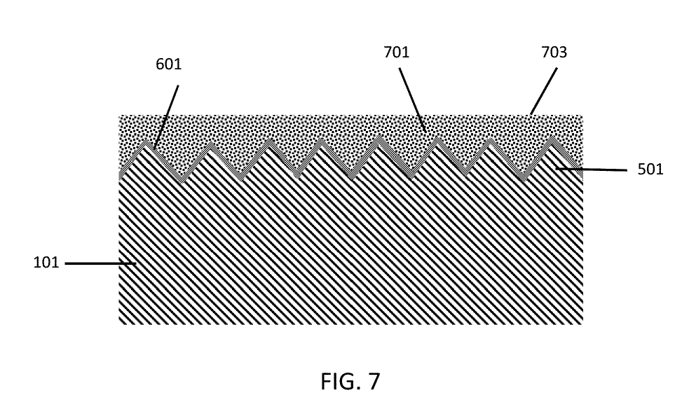

Adverting to FIG. 7, a SRB layer 701 is deposited over the low-temperature seed layer 601. The upper surface 703 of SRB layer 701 is shown planarized. Planarization can be performed with CMP. The SRB layer 701 is formed over the low-temperature seed layer 601 to a thickness of 200 to 500 nm. The SRB layer 701 includes a high mobility channel material including Ge, InGaAs, or GaₓIn₁₋ₓAs_{y}P_{1-y}. Following the planarization of the SRB layer 701, the silicon wafer 101 can be further processed such as adding channels. The pyramids 501 can be detected by cross-sectional transmission electron microscopy (X-TEM).

The embodiments of the present disclosure can achieve several technical effects, such as the formation of a uniformly textured Si wafer with a low cost patterning such that a thin SRB layer with reduced defect density can be formed over the textured wafer.

Devices formed in accordance with embodiments of the present disclosure enjoy utility in various industrial applications, e.g., microprocessors, smart-phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in the manufacture of any of various types of highly integrated semiconductor devices using Si wafers having thin SRB layers with reduced defect density. The present disclosure is particularly applicable to the 14 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a mask over an upper surface of a silicon (Si) wafer;
patterning the mask by direct-self assembly (DSA);
etching the Si wafer through the patterned mask to form holes in the Si wafer;
removing the mask;
direction-preferential etching the holes to form a textured surface in the Si wafer;
epitaxially growing a low-temperature seed layer on the textured surface of the Si wafer;
forming a stress relaxed buffer (SRB) layer over the low-temperature seed layer; and
planarizing an upper surface of the SRB layer.

2. The method according to claim 1, comprising:
wet or dry etching the Si wafer through the patterned mask to form the holes in a uniform distribution having a separation of 30 to 300 nm between adjacent holes and an individual hole diameter of 10 to 300 nm.

3. (canceled)

4. The method according to claim 1, comprising:
direction-preferential etching with tetramethylammonium hydroxide (TMAH), hydrogen chloride (HCl) or potassium hydroxide (KOH).

5. The method according to claim 1, wherein etching the holes to form the textured surface comprises:
forming pyramids having a depth of 50 to 300 nm in the upper surface of the Si wafer.

6. The method according to claim 5, wherein the pyramids have a Si <111> surface.

7. The method according to claim 1, wherein the step of forming the textured surface includes:
forming inverted pyramids having a Si <111> surface.

8. (canceled)

9. The method according to claim 1, further comprising:
planarizing the upper surface of the SRB layer with chemical-mechanical planarization (CMP); and
epitaxially growing the low-temperature seed layer in trenches of the textured surface of the Si wafer.

10. The method according to claim 1, further comprising:
forming a graded SRB stacked epitaxial layer on the textured surface of the Si wafer.

11. The method according to claim 9, further comprising:
epitaxially growing the low-temperature seed layer to a thickness of 10 nm to 40 nm.

12. The method according to claim 1, wherein the low-temperature seed layer comprises germanium (Ge), indium phosphide (InP), or gallium arsenide (GaAs).

13. The method according to claim 1, further comprising:
epitaxially growing the SRB layer over the low-temperature seed layer to a thickness of 200 nm to 500 nm,
wherein the SRB layer includes silicon germanium (SiₓGe₁₋ₓ), indium gallium arsenide (InGaAs), or indium gallium arsenide phosphide (GaₓIn₁₋ₓAs_{y}P_{1-y}).

14. A method comprising:
forming a mask over an upper surface of a silicon (Si) wafer;
patterning the mask by direct-self assembly (DSA);
etching the Si wafer through the patterned mask to form holes in the Si wafer;
removing the mask;
direction-preferential etching the holes to form a textured surface in the Si wafer, wherein the textured surface includes a Si <111> surface;
epitaxially growing a low-temperature seed layer on the textured surface of the Si wafer, the low-temperature seed layer comprising germanium (Ge), indium phosphide (InP), or gallium arsenide (GaAs);
epitaxially growing a SRB layer over the low-temperature seed layer to a thickness of 200 nm to 300 nm, wherein the SRB layer comprises silicon germanium (SiₓGe₁₋ₓ), indium gallium arsenide (InGaAs), or indium gallium arsenide phosphide (GaₓIn₁₋ₓAs_{y}P_{1-y}); and
planarizing an upper surface of the SRB layer.

15. The method according to claim 14, comprising:
wet or dry etching the Si wafer through the patterned mask to form the holes in a uniform distribution having a separation of 30 to 300 nm between adjacent holes and an individual hole diameter of 10 to 300 nm.

16. The method according to claim 14, comprising:
direction-preferential etching the holes to form the textured surface in the Si wafer to form pyramids in the upper surface of the Si wafer, wherein the pyramids have a depth of 50 to 300 nm.

17. The method according to claim 16, comprising:
direction-preferential etching with tetramethylammonium hydroxide (TMAH), hydrogen chloride (HCl) or potassium hydroxide (KOH).

18. A device comprising:
a silicon (Si) wafer having a textured surface comprising a uniform distribution of pyramids, the pyramids having a depth of less than 300 nm;
an epitaxially grown low-temperature seed layer formed on the textured surface of the Si wafer; and
a stress relaxed buffer (SRB) layer deposited over the low-temperature seed layer.

19. The device according to claim 18, wherein the uniform distribution of pyramids has a Si <111> surface.

20. The device according to claim 18, wherein the low-temperature seed layer comprises germanium (Ge), indium phosphide (InP), or gallium arsenide (GaAs), and the SRB layer comprises silicon germanium (SiₓGe₁₋ₓ), indium gallium arsenide (InGaAs), or indium gallium arsenide phosphide (GaₓIn₁₋ₓAs_{y}P_{1-y}).
